(19) United States
(12) Patent Application Publication
(10) Pub. No.: US 2026/0123071 A1
(43) Pub. Date: Apr. 30, 2026

(54) CAP FOR AN OPTICAL SENSOR PACKAGE AND METHOD OF MANUFACTURE

(71) Applicant: STMicroelectronics International N.V., Geneva (CH)

(72) Inventor: Jing-En LUAN, Singapore (SG)

(73) Assignee: STMicroelectronics International N.V., Geneva (CH)

(21) Appl. No.: 18/971,311

(22) Filed: Dec. 6, 2024

Related U.S. Application Data
(60) Provisional application No. 63/617,901, filed on Jan. 5, 2024.

(51) Int. Cl. H10F 39/00

(52) U.S. Cl. CPC H10F 39/804; H10F 39/024; H10F 39/8057; H10F 39/806

(57) ABSTRACT

A cap for an optical integrated circuit package is formed by a molded body including a peripheral side wall and a front wall. The front wall of the cap laterally encapsulates a stack of a clear plate and a diffractive optical element. The peripheral side wall extends from the front wall and includes portions which extend over a rear surface of the stack such that peripheral edge regions of the stack are encapsulated between the front wall of the cap and the peripheral side wall of the cap.

### CROSS REFERENCE TO RELATED APPLICATIONS

This application claims priority from United States Provisional Application for Patent No. 63/617,901, filed Jan. 5, 2024, the disclosure of which is incorporated herein by reference.

### TECHNICAL FIELD

The present invention generally relates to the packaging of optical integrated circuits and, in particular, to a cap for an optical integrated circuit package.

### BACKGROUND

Reference is made to FIG. 1 which shows a cross-sectional view of an optical integrated circuit package 10. The package 10 includes a package substrate 12, for example in the form of a multilayer board 14 (for example, of printed circuit board type) including an interconnection network 16 (formed of wire lines and vias) that electrically connects front electrical pads 18 to rear electrical pads 20. The rear electrical pads 20 may comprise, for example, parts of a redistribution layer (RDL). Although not explicitly shown, it will be noted that the front and rear surfaces of the package substrate 12 may include a solder masking layer with openings at the locations of the pads 18 and 20. The rear electrical pads 20 may comprise, for example, support pads for pillars 21p or balls 21b (in a ball grid array (BGA) type package). The rear electrical pads 20 may comprise, for example, connection solder pads (in a land grid array (LGA) type package).

An optical integrated circuit sensor die 22s and an optical integrated circuit emitter die 22e are mounted to the upper surface of the package substrate 12 using a suitable adhesive material (for example, a die attach film (DAF)). The optical integrated circuit sensor die 22s includes, associated with a surface (for example, a front surface) opposite the surface (for example, a rear surface) attached to the package substrate 12, an optical sensor 24s (for example, formed by an array of photosensitive elements such as photodiodes) and a plurality of electrical connection die bonding pads 26. The optical integrated circuit emitter die 22e includes, associated with a surface (for example, a front surface) opposite the surface (for example, a rear surface) attached to the package substrate 12, an optical emitter 24e (for example, comprising a vertical cavity surface-emitting laser (VCSEL)) and one or more electrical connection die bonding pads 26.

The electrical connection die bonding pads 26 of the optical integrated circuit dies 22s, 22e are electrically connected to the front electrical pads 18 of the package substrate 12 using bonding wires 28. An electrical connection may further be provided between the rear surfaces of the optical integrated circuit sensor die 22s and optical integrated circuit emitter die 22e and associated front electrical pads 18 of the package substrate 12.

A cap 30 is mounted to the package substrate 12. The cap 30 is formed of an injection molded opaque material and includes a peripheral side wall 30a, a divider wall 30b and a front wall 30c. The peripheral side wall 30a and front wall 30c define an open space of the cap 30 and the divider wall 30b extends between opposed side walls to divide the open space into a first cavity 32a and a second cavity 32b. With the cap 30 installed on the package substrate 12, the optical integrated circuit sensor die 22s is housed within the first cavity 32a and the optical integrated circuit emitter die 22e is housed within the second cavity 32b. The distal ends of the peripheral side walls 30a and divider wall 30b are attached to the upper surface of the package substrate 12 using a layer of adhesive material.

The front wall 30c of the cap 30 includes a first through aperture 34a into the first cavity 32a. The first through aperture 34a is aligned with the location of the optical sensor 24s. The front wall 30c further includes a second through aperture 34b into the second cavity 32b. The second through aperture 34b is aligned with the location of the optical emitter 24e. A first diffractive optical element (DOE) 36a (for example, including one or more of an optical lens and an optical filter (for example, an infrared (IR) filter), and having a form of a flat plate) is attached to the front wall 30c of the cap 30 using an adhesive layer (not explicitly shown). The first DOE 36a is mounted within the cavity 32a at the back surface of the front wall 30c to cover the first through aperture 34a. A second diffractive optical element (DOE) 36b (for example, including one or more of an optical lens and an optical filter (for example, an infrared (IR) filter), and having a form of a flat plate) is attached to the front wall 30c of the cap 30 using an adhesive layer (not explicitly shown). The second DOE 36b is mounted within the cavity 32b at the back surface of the front wall 30c to cover the second through aperture 34b.

There is a need in the art for an improved cap for an optical integrated circuit package.

### SUMMARY

In an embodiment, a method comprises: providing a first panel carrier including a plurality of cap zones which are separated from each other by inter-cap zones; mounting to the first panel carrier, at each cap zone, a stack of a clear plate and a diffractive optical element; molding a first encapsulating resin material on the first panel carrier to laterally encapsulate the stack at each cap zone and form a first encapsulated panel structure; attaching a second panel carrier to the first encapsulated panel structure on a side thereof which is opposite the first panel carrier; removing the first panel carrier; molding a second encapsulating resin material on the first encapsulated panel structure to form a second encapsulated panel structure having a cavity in the second encapsulating resin material which exposes each stack; cutting the second encapsulated panel structure at the inter-cap zones to singulate the second encapsulated panel structure into a plurality of caps; and removing the plurality of caps from the second panel carrier.

In an embodiment, a cap for an optical integrated circuit package comprises: a molded body including a peripheral side wall and a front wall; wherein the front wall laterally encapsulates a stack of a clear plate and a diffractive optical element; wherein the peripheral side wall extends from the front wall and includes portions which extend over a portion of a rear surface of the stack such that peripheral edge regions of the stack are encapsulated between the front wall of the cap and the peripheral side wall of the cap. The front wall of the cap and the peripheral side wall of the cap define an open space of the cap within which an integrated circuit of the optical integrated circuit package is housed.

An optical integrated circuit package comprises: a cap that includes a molded body including a peripheral side wall and a front wall; wherein the front wall laterally encapsulates a stack of a clear plate and a diffractive optical element; wherein the peripheral side wall extends from the front wall and includes portions which extend over a portion of a rear surface of the stack such that peripheral edge regions of the stack are encapsulated between the front wall of the cap and the peripheral side wall of the cap; and wherein the front wall of the cap and the peripheral side wall of the cap define an open space of the cap; a package substrate; and an integrated circuit die mounted to the package substrate; wherein the cap is mounted to the package substrate with the integrated circuit die housed within the open space.

### BRIEF DESCRIPTION OF THE DRAWINGS

For a better understanding of the embodiments, reference will now be made by way of example only to the accompanying figures in which:

FIG. 1 shows a cross-sectional view of an optical integrated circuit package;

FIG. 2 shows a cross-sectional view of an optical integrated circuit package;

FIGS. 3A-3K illustrate steps in a process for manufacturing the cap used in the package as shown in FIG. 2; and

FIG. 4 shows a cross-sectional view of an embodiment of the cap.

### DETAILED DESCRIPTION

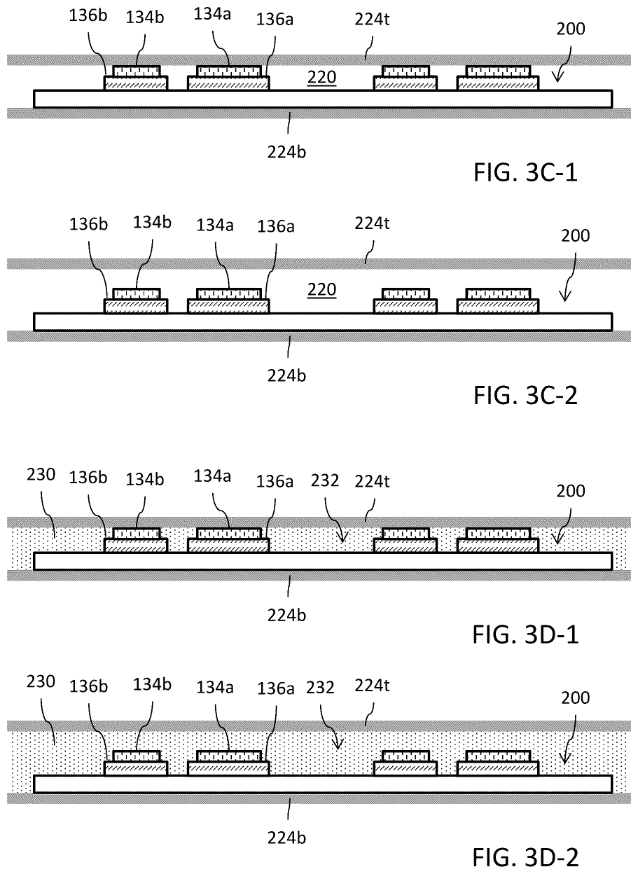

Reference is made to FIG. 2 which shows a cross-sectional view of an optical integrated circuit package 110. The package 110 includes a package substrate 112, for example in the form of a multilayer board 114 (for example, of printed circuit board type) including an interconnection network 116 (formed of wire lines and vias) that electrically connects front electrical pads 118 to rear electrical pads 120. The rear electrical pads 120 may comprise, for example, parts of a redistribution layer (RDL). Although not explicitly shown, it will be noted that the front and rear surfaces of the package substrate 112 may include a solder masking layer with openings at the locations of the pads 118 and 120. The rear electrical pads 120 may comprise, for example, support pads for pillars 121p or balls 121b (in a ball grid array (BGA) type package). The rear electrical pads 120 may comprise, for example, connection solder pads (in a land grid array (LGA) type package).

An optical integrated circuit sensor die 122s and an optical integrated circuit emitter die 122e are mounted to the upper surface of the package substrate 112 using a suitable adhesive material (for example, a die attach film (DAF)). The optical integrated circuit sensor die 122s includes, associated with a surface (for example, a front surface) opposite the surface (for example, a rear surface) attached to the package substrate 112, an optical sensor 124s (for example, formed by an array of photosensitive elements such as photodiodes) and a plurality of electrical connection die bonding pads 126. The optical integrated circuit emitter die 122e includes, associated with a surface (for example, a front surface) opposite the surface (for example, a rear surface) attached to the package substrate 112, an optical emitter 124e (for example, comprising a vertical cavity surface-emitting laser (VCSEL)) and one or more electrical connection die bonding pads 126.

The electrical connection die bonding pads 126 of the optical integrated circuit dies 122s, 122e are electrically connected to the front electrical pads 118 of the package substrate 112 using bonding wires 128. An electrical connection may further be provided between the rear surfaces of the optical integrated circuit sensor die 122s and optical integrated circuit emitter die 122e and associated front electrical pads 118 of the package substrate 112.

Although FIG. 2 shows the optical integrated circuit dies 122s, 122e mounted in normal orientation with their back sides mounted to the package substrate 112 and front sides face up, it will be understood that this is by way of example only and that in an alternate implementation one or the other or both of the optical integrated circuit dies 122s, 122e may be mounted in so-called “flip-chip” orientation with their front side mounted to the package substrate 112 (face down) and the electrical connection die bonding pads 126 being soldered directly to the front electrical pads 118 of the package substrate 112.

A cap 130 is mounted to the package substrate 112. The cap 130 is formed by a body of an injection molded opaque material and includes a peripheral side wall 130a, a divider wall 130b and a front wall 130c. As will be explained in more detail herein, the front wall 130c is formed by one injection molding operation and the peripheral side wall 130a and divider wall 130b are formed in another (i.e., different) injection molding operation. The illustrated dotted line indicates a location between the encapsulation materials formed by the two injection molding operations (noting however that the line of demarcation between the materials of the two injection molding operations may not necessarily be completely visible or detectable in all cases).

Positioned over the optical integrated circuit sensor die 122s is a stack of a first clear resin plate 134a and a first diffractive optical element (DOE) 136a (for example, including one or more of an optical lens and an optical filter (for example, an infrared (IR) filter), and having a form of a flat plate). Positioned over the optical integrated circuit emitter die 122e is a stack of a second clear resin plate 134b and a second diffractive optical element (DOE) 136a (for example, including one or more of an optical lens and an optical filter (for example, an infrared (IR) filter). Each of the resin plate 134 and DOE 136 may have a parallelepipedal shape. An area of each resin plate 134 is smaller than an area of the DOE 136 on which the resin plate is stacked (wherein area in this context refers to the width×length of the major (i.e., largest) face of the parallelepiped). The front wall 130c of the cap 130 laterally encapsulates the stack of clear resin plate 134a and DOE 136a as well as the stack of clear resin plate 134b and DOE 136b. The peripheral side walls 130a and divider wall 130b of the cap 130 extend rearwardly from the front wall 130c of the cap 130. Portions of the peripheral side walls 130a and divider wall 130b extend over a portion of the rear surfaces of the DOEs 136a, 136b, such that the peripheral edge regions 138 of the DOEs 136a, 136b (i.e., those regions which are not covered by the smaller area occupying resin plates 134a, 134b) are encapsulated between the front wall 130c of the cap 130 and the peripheral side walls 130a and divider wall 130b.

The peripheral side wall 130a, front wall 130c and stacks of clear resin plate 134a, 134b and DOE 136a, 136b define an open space of the cap 130 and the divider wall 130b extends between opposed side walls to divide the open space into a first cavity 132a and a second cavity 132b. With the cap 130 installed on the package substrate 112, the optical integrated circuit sensor die 122s is housed within the first cavity 132a and the optical integrated circuit emitter die 122e is housed within the second cavity 132b. The distal ends of the peripheral side walls 130a and divider wall 130b are attached to the upper surface of the package substrate 112 using a layer of adhesive material.

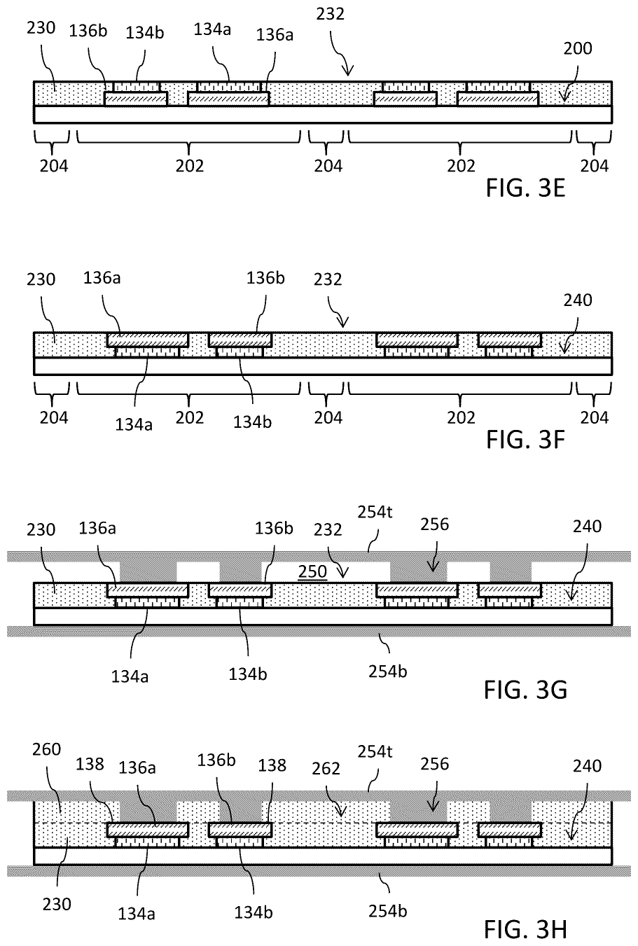

Reference is now made to FIGS. 3A-3J which illustrate steps in a process for manufacturing the cap 130 as used in the package 110 shown in FIG. 2.

FIG. 3A-a first panel carrier 200 includes a plurality of cap zones 202 which are separated from each other by inter-cap zones 204. A plurality of singulated diffractive optical elements 206 are mounted to the first panel carrier 200 at the cap zones 202. The singulated diffractive optical elements 206 mounted at each cap zone 202 include the first DOE 136a and the second DOE 136b. The first DOE 136a and the second DOE 136b are spaced apart from each other at each cap zone 202.

FIG. 3B-a clear resin block 210 is formed on top of each singulated diffractive optical element 206. In an embodiment, a clear resin material may be screen printed on the upper surface of the diffractive optical elements 206 and subjected to a baking process to cure the resin material to form the resin blocks 210. The clear resin block 210 mounted at each cap zone 202 includes the first clear resin plate 134a forming a stack with the first DOE 136a and the second clear resin plate 134b forming a stack with the second DOE 136b. An area (for example, the surface of the parallelepiped in a plane parallel to the mounting surface of the first panel carrier 200) of each clear resin block 210 is smaller than an area (in a plane parallel to the mounting surface of the first panel carrier 200) of the singulated diffractive optical elements 206 on which the clear resin block 210 is mounted to form the stack.

It will be noted that structures in addition to the diffractive optical elements 206 could be mounted to the first panel carrier 200 at the cap zones 202. For example, a structure for assisting in providing electromagnetic shielding could be provided. Additionally, a passive or active electronic device could be provided.

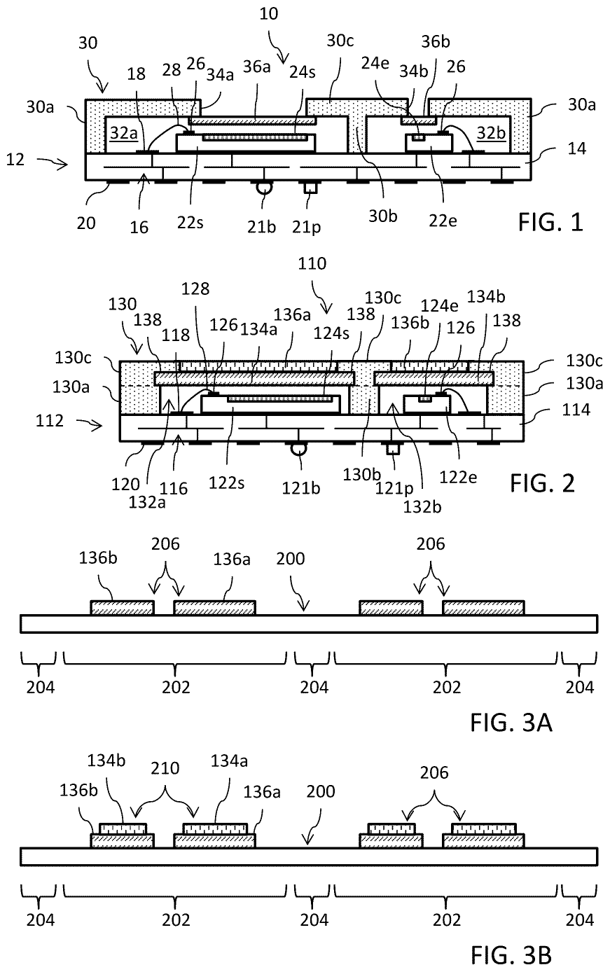

FIGS. 3C-1 and 3C-2—the first panel carrier 200 with stacks of a clear resin plate 134 on a DOE 136 is then placed within the cavity 220 of a mold 224. As shown in FIG. 3C-1, a top (or upper) mold half 224t of the mold 224 is placed in contact with the upper surfaces of the clear resin plates 134a, 134b and a bottom (or lower) mold half 224b of the mold 224 is placed in contact with the bottom surface of the first panel carrier 200. Alternatively, as shown in FIG. 3C-2, only the bottom surface of the first panel carrier 200 is placed in contact with the lower mold half 224b of the mold 224.

FIGS. 3D-1 and 3D-2—the cavity 220 of the mold 224 is then filled with an opaque encapsulating resin material 230 to produce an encapsulated panel structure 232.

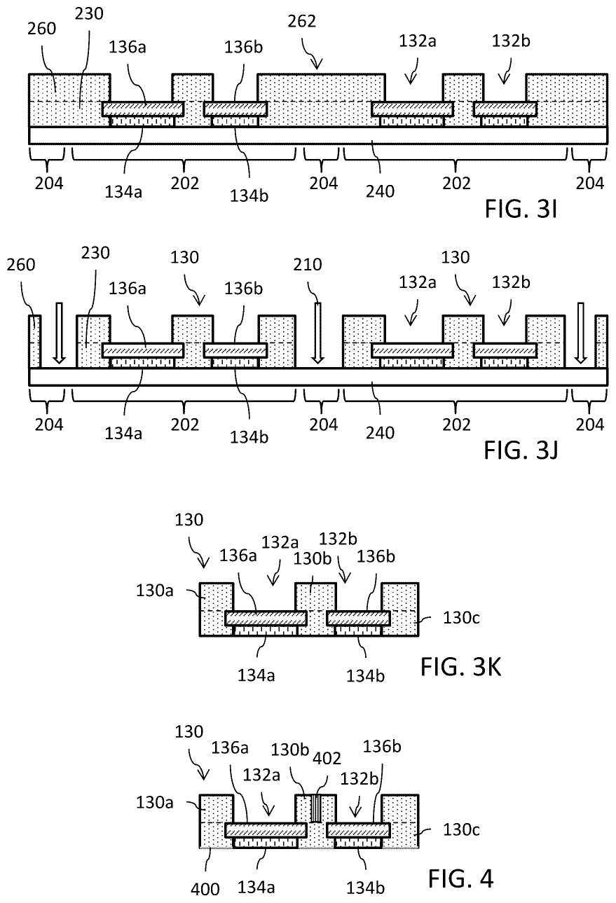

The encapsulated panel structure 232 is removed from the mold 224. For the embodiment as in FIGS. 3C-2 and 3D-2, the encapsulating resin material 230 covering the clear resin plates 134a, 134b is removed using a grinding or polishing operation so that the upper surfaces of the clear resin plates 134a, 134b are exposed from the encapsulating resin material 230. Similarly, the grinding or polishing operation may be used to remove unwanted encapsulating resin material 230 (for example, in the form of molding flash) which may be present on the upper surfaces of the clear resin plates 134a, 134b when molding using the embodiment as in FIGS. 4C-1 and 4D-1.

The resulting encapsulated panel structure 232 is shown in FIG. 3E. It will be noted that structure for the front wall 130c of the cap 130 being produced is formed by portions of the opaque encapsulating resin material 230 which laterally encapsulates the stacks of the resin plates 134a, 134b and DOEs 136a, 136b. Furthermore, if any additional structure (for example, electromagnetic shielding and passive or active electronic devices) was mounted to the first panel carrier 200 at the cap zones 202, such structure would also be encapsulated by the opaque encapsulating resin material 230.

FIG. 3F-a second panel carrier 240 is mounted to the encapsulated panel structure 232 on a side thereof which is opposite the first panel carrier 200. The first panel carrier 200 is then removed. The encapsulated panel structure 232 supported by second panel carrier 240 is then flipped up-side-down.

FIG. 3G—the second panel carrier 240 with encapsulated panel structure 232 is then placed within the cavity 250 of a mold 254. The mold 254 is a two-piece mold including a top (or upper) mold half 254t and a bottom (or lower) mold half 254b. The top mold half 254t includes a plurality of projections 256, wherein each projection 256 is located in alignment with a corresponding stack of a clear resin plate 134 and a DOE 136. The bottom of each projection 256 for the top mold half 254t of the mold 254 is placed in sealing contact with the upper surface of the clear resin plate 134 and the bottom mold half 254b of the mold 254 is placed in contact with the bottom surface of the second panel carrier 240.

It will be noted that structures could be mounted to the encapsulated panel structure 232 at the cap zones 202. For example, a structure for assisting providing electromagnetic shielding could be provided. Additionally, a passive or active electronic device could be provided.

FIG. 3H—the cavity 250 of the mold 254 is then filled with an opaque encapsulating resin material 260 to produce a further encapsulated panel structure 262. In an embodiment, the opaque encapsulating resin material 260 is the same material as the opaque encapsulating resin material 230 used in the injection molding operation of FIGS. 3D-1 and 3D-2. The illustrated dotted line indicates a location between encapsulation material formed by the two injection molding operations. It will be noted that the peripheral edge regions 138 of the DOEs 136a, 136b are encapsulated between the opaque encapsulating resin material 230 (forming the front wall 130c of the cap 130) and the opaque encapsulating resin material 260 (forming the peripheral side walls 130a and divider wall 130b). This ensures secure retention of the stacks of the resin plates 134a, 134b and DOEs 136a, 136b within the cap 130.

The further encapsulated panel structure 262 is removed from the mold 254. The resulting further encapsulated panel structure 262 is shown in FIG. 3I. It will be noted that structure for the peripheral side wall 130a and divider wall 130b is formed by portions of the opaque encapsulating resin material 260, and the first cavity 132a and second cavity 132b are formed in the opaque encapsulating resin material 260 at the locations of the projection 256 for the top mold half 254t to expose each stack of resin plate 134 and DOE 136. The opaque encapsulating resin materials 230, 260 encapsulate and secure the stacks of the resin plates 134a, 134b and DOEs 136a, 136b. Furthermore, if any additional structure (for example, electromagnetic shielding and passive or active electronic devices) was mounted to the encapsulated panel structure 232 at the cap zones 202, such structure would also be encapsulated by the opaque encapsulating resin material 260.

FIG. 3J-a cutting process is then performed at the inter-cap zones 204 to singulate (also referred to in the art as dice) the further encapsulated panel structure 262 into a plurality of caps 130. The cutting at the inter-cap zones 204 during singulation (dicing) may, for example, be made using a saw or laser (schematically indicated by arrow 270). The cutting operation may, if desired, extend completely through the second panel carrier 240 as well. The caps 130 are then removed from the second panel carrier 240 to produce individual caps 130 like the one shown in FIG. 3K.

Reference is now made to FIG. 4 which shows a cross-section of the cap 130 which includes additional structures encapsulated within the opaque encapsulating resin materials 230, 260. For example, the cap 130 in FIG. 4 shows an electromagnetic shield 400 encapsulated within the front wall 130c (formed by opaque encapsulating resin material 230) and an electronic device 402 encapsulated within the divider wall 130b (formed by opaque encapsulating resin material 260). Suitable electrical connections to the electromagnetic shield 400 and/or electronic device 402 may be provided at the distal ends of the walls 130b and 103c in support of making an electrical coupling to the package substrate 112. The provision of the electromagnetic shield 400 encapsulated within the front wall 130c is by example only, it being understood that the electromagnetic shield 400 could instead be encapsulated within walls 130a, 103b. The provision of the device 402 encapsulated within the divider wall 130b is by example only, it being understood that the device 402 could instead be encapsulated within peripheral side wall 130a.

The cap 130 used in the package of FIG. 2 exhibits a number of advantages over the cap 30 used in the package of FIG. 1 including: lower cost to manufacture, easier process of manufacture, smaller form factor, integration of the optics (stack of the resin plate 134 and DOE 136) encapsulated within the body of the cap, improved adhesion and retention of the plate/DOE stack within the cap, possibility to integrate active and/or passive electronic devices within the cap by encapsulated molding, possibility to provide electromagnetic shielding within the cap by encapsulated molding, and improved heat dispersion.

In an embodiment, the optical integrated circuit package 110 may form a time-of-flight (ToF) device where light (for example, at infrared wavelength) emitted from the optical emitter 124e of the optical integrated circuit emitter die 122e passes through the stack of second clear resin plate 134b and second DOE 136b to illuminate a target. The emitted light reflected by the target passes through the first clear resin plate 134a and first DOE 136a to be detected by the optical sensor 124s of the optical integrated circuit sensor die 122s. Processing of the detected reflected light in view of the emitted illuminating light can provide information regarding a distance from the optical integrated circuit package 110 to the target.

Although the optical integrated circuit package 110 shown in FIG. 2 includes two cavities 132, it will be understood that this is by way of example only and the package 110 may include only one cavity housing one or more optical integrated circuit dies.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A method, comprising:
providing a first panel carrier including a plurality of cap zones which are separated from each other by inter-cap zones;
mounting to the first panel carrier, at each cap zone, a stack of a clear plate and a diffractive optical element;
molding a first encapsulating resin material on the first panel carrier to laterally encapsulate the stack at each cap zone and form a first encapsulated panel structure;
attaching a second panel carrier to the first encapsulated panel structure on a side thereof which is opposite the first panel carrier;
removing the first panel carrier;
molding a second encapsulating resin material on the first encapsulated panel structure to form a second encapsulated panel structure having a cavity in the second encapsulating resin material which exposes each stack;
cutting the second encapsulated panel structure at the inter-cap zones to singulate the second encapsulated panel structure into a plurality of caps; and
removing the plurality of caps from the second panel carrier.

2. The method of claim 1, wherein molding the second encapsulating resin material on the first encapsulated panel structure comprises placing the first encapsulated panel structure within a mold having a first mold half in contact with the second panel carrier and a first mold half with projections in contact with each stack to define the cavity.

3. The method of claim 1, wherein the first and second encapsulating resin materials are a same material.

4. The method of claim 1, wherein mounting the stack at each cap zone comprises:
mounting the diffractive optical element to the first carrier panel at each cap zone; and
mounting the clear plate to an upper surface of each diffractive optical element.

5. The method of claim 4, wherein mounting the clear plate comprises:
printing a layer of resin material to the upper surface of each diffractive optical element; and
curing the layer of resin material to form the clear plate.

6. The method of claim 4, wherein molding the first encapsulating resin material on the first panel carrier comprises placing the first panel carrier with stacks within a mold having a first mold half in contact with the first panel carrier and a second mold half in contact with the clear plate at each cap zone.

7. The method of claim 1, wherein molding the first encapsulating resin material on the first panel carrier comprises placing the first panel carrier with stacks within a mold having a first mold half in contact with the first panel carrier and a second mold half in contact with the stack at each cap zone.

8. The method of claim 1, wherein cutting the second encapsulated panel structure at the inter-cap zones forms peripheral side walls of the cap.

9. The method of claim 1, wherein molding the first encapsulating resin material on the first panel carrier forms a front wall of the cap, said front wall laterally encapsulating the stack.

10. The method of claim 1, further comprising mounting to the first panel carrier, at each cap zone, a structure providing one of an electromagnetic shield or an electronic device, wherein said structure is encapsulated by the first encapsulating resin material within the first encapsulated panel structure.

11. The method of claim 1, further comprising mounting to the first encapsulated panel structure, at each cap zone, a structure providing one of an electromagnetic shield or an electronic device, wherein said structure is encapsulated by the second encapsulating resin material within the second encapsulated panel structure.

12. A cap for an optical integrated circuit package, comprising:
a molded body including a peripheral side wall and a front wall;
wherein the front wall laterally encapsulates a stack of a clear plate and a diffractive optical element;
wherein the peripheral side wall extends from the front wall and includes portions which extend over a portion of a rear surface of the stack such that peripheral edge regions of the stack are encapsulated between the front wall of the cap and the peripheral side wall of the cap.

13. The cap of claim 12, wherein an area of the clear plate is smaller than an area of the diffractive optical element.

14. The cap of claim 13, wherein a peripheral edge region of the diffractive optical element not covered by the clear plate is encapsulated between the front wall of the cap and the peripheral side wall of the cap.

15. The cap of claim 12, further comprising one of an electromagnetic shield or an electronic device encapsulated within the peripheral side wall.

16. The cap of claim 12, further comprising one of an electromagnetic shield or an electronic device encapsulated within the front wall.

17. The cap of claim 12, wherein the front wall of the cap and the peripheral side wall of the cap define an open space of the cap within which an integrated circuit of the optical integrated circuit package is housed.

18. An optical integrated circuit package, comprising:
a cap comprising:
a molded body including a peripheral side wall and a front wall;
wherein the front wall laterally encapsulates a stack of a clear plate and a diffractive optical element;
wherein the peripheral side wall extends from the front wall and includes portions which extend over a portion of a rear surface of the stack such that peripheral edge regions of the stack are encapsulated between the front wall of the cap and the peripheral side wall of the cap; and
wherein the front wall of the cap and the peripheral side wall of the cap define an open space of the cap;
a package substrate; and
an integrated circuit die mounted to the package substrate;
wherein the cap is mounted to the package substrate with the integrated circuit die housed within the open space.

19. The optical integrated circuit package of claim 18, wherein a peripheral edge region of the diffractive optical element not covered by the clear plate is encapsulated between the front wall of the cap and the peripheral side wall of the cap.

20. The optical integrated circuit package of claim 18, further comprising one of an electromagnetic shield or an electronic device encapsulated within the molded body of the cap.
